(19) United States
(12) Patent Application Publication
(10) Pub. No.: US 2025/0324854 A1
(43) Pub. Date: Oct. 16, 2025

(54) DISPLAY DEVICE

(71) Applicant: Samsung Display Co., LTD., Yongin-si (KR)

(72) Inventors: Hyun Eok SHIN, Yongin-si (KR); Do Keun SONG, Yongin-si (KR)

(21) Appl. No.: 18/943,704

(22) Filed: Nov. 11, 2024

(30) Foreign Application Priority Data
Apr. 16, 2024 (KR) 10-2024-0050729

(51) Int. Cl. H10K 59/122

(52) U.S. Cl. CPC H10K 59/122

(57) ABSTRACT

A display device includes a substrate including a display area, and a non-display area around the display area, a passivation layer above the substrate, a light-emitting element above the passivation layer, a pixel-defining layer above the passivation layer in the display area and the non-display area, and including a first inorganic layer above the substrate, a second inorganic layer above the first inorganic layer, and a third inorganic layer above the second inorganic layer, in the display area, and the first inorganic layer and the second inorganic layer, in the non-display area, a first bank above the pixel-defining layer, and a second bank above the first bank, and extending further than a side of the first bank.

### CROSS-REFERENCE TO RELATED APPLICATION

The present application claims priority to, and the benefit of, Korean Patent Application No. 10-2024-0050729, filed on Apr. 16, 2024, in the Korean Intellectual Property Office, the entire disclosure of which is incorporated herein by reference.

### BACKGROUND

### 1. Field

The present disclosure relates to a display device.

### 2. Description of the Related Art

With the advancement of the information age, the demand for a display device for displaying an image has increased with various forms. For example, the display device has been applied to various electronic devices, such as a smart phone, a digital camera, a laptop computer, a navigator and a smart television. The display device may be a flat panel display device, such as a liquid crystal display device, a field emission display device and an organic light-emitting display device. Among the flat panel display devices, the light-emitting display device includes a light-emitting element in which each of pixels of a display panel may self-emit light, thereby displaying an image even without a backlight unit that provides the display panel with light.

Recently, the display device has been applied to a glasses-type device for providing virtual reality and augmented reality. To be applied to the glasses-type device, the display device is implemented at a very small size of about 2 inches or less, but it should have high pixel integration so that it may be implemented at high resolution. For example, the display device may have high pixel integration of about 400 pixels per inch (PPI) or more.

### SUMMARY

An aspect of the present disclosure provides a display device in which light-emitting elements or common electrodes, which are divided for each light emission area, may be formed without a mask process.

An aspect of the present disclosure provides a display device in which moisture absorption or moisture permeation of a lower organic layer of a light-emitting element is reduced to enhance durability.

The aspects of the present disclosure are not limited to those mentioned above, and additional aspects of the present disclosure, which are not mentioned herein, will be clearly understood by those skilled in the art from the following description of the present disclosure.

According to the display device according to one or more embodiments, an organic layer of a non-display area is covered with a pixel-defining layer, and thus may be robust against moisture absorption or moisture permeation.

According to one or more embodiments of the disclosure, a display device includes a substrate including a display area, and a non-display area around the display area, a passivation layer above the substrate, a light-emitting element above the passivation layer, a pixel-defining layer above the passivation layer in the display area and the non-display area, and including a first inorganic layer above the substrate, a second inorganic layer above the first inorganic layer, and a third inorganic layer above the second inorganic layer, in the display area, and the first inorganic layer and the second inorganic layer, in the non-display area, a first bank above the pixel-defining layer, and a second bank above the first bank, and extending further than a side of the first bank.

In at least a portion of the non-display area, the second inorganic layer may be uncovered by the third inorganic layer.

A side of the third inorganic layer that faces the non-display area may extend further than, or is aligned with, a side of the second bank that faces the non-display area.

The pixel-defining layer may be on an upper surface and a side of the passivation layer.

An angle between a lower surface and the side of the passivation layer may be less than about 90°.

The pixel-defining layer may include a first portion at a first height above the substrate, a second portion at a second height above the substrate, and a third portion at a third height above the substrate, wherein the first height is greater than the second height and the third height, wherein the second height is greater than the third height, and wherein the first portion, the second portion, and the third portion of the pixel-defining layer are sequentially arranged in a longitudinal direction of the substrate.

The passivation layer may extend in the display area and the non-display area.

A thickness of the first inorganic layer may be less than a thickness of the second inorganic layer.

A thickness of the first inorganic layer may be less than a thickness of a pixel electrode of the light-emitting element.

The second inorganic layer may include a first side facing a side of the pixel electrode, and a second side extending further than the first side.

The second inorganic layer may include a different material from the first inorganic layer and the third inorganic layer.

The first inorganic layer and the third inorganic layer may include silicon nitride, wherein the second inorganic layer includes one or more of silicon oxynitride or silicon oxide.

The passivation layer may include one or more of an acrylic resin, an epoxy resin, a phenolic resin, a polyamide resin, or a polyimide resin.

In the display area, the pixel-defining layer may include a side extending further than the side of the first bank.

The display device may further include a residual pattern at an edge of a pixel electrode of the light-emitting element, below the pixel-defining layer.

The light-emitting element may include a pixel electrode above the passivation layer, a light-emitting layer above the pixel electrode, and a common electrode above the light-emitting layer and contacting the first bank.

The display device may further include a first inorganic pattern above the light-emitting element in the display area, and a second inorganic pattern above the pixel-defining layer in the non-display area, and spaced apart from the first inorganic pattern.

The first inorganic pattern may be below a lower surface of the second bank.

According to one or more embodiments of the disclosure, a display device includes a light-emitting element above a substrate, a pixel-defining layer above the substrate, including a first inorganic layer above the substrate, a second inorganic layer above the first inorganic layer, and a third inorganic layer above the second inorganic layer, a first bank above the pixel-defining layer, and a second bank above the first bank, and extending further than a side of the first bank, wherein the third inorganic layer has different respective thicknesses in an area overlapping the first bank and in an area non-overlapping with the first bank.

The thickness of the third inorganic layer in the area overlapping the first bank may be greater than the thickness of the third inorganic layer in the area non-overlapping with the first bank.

According to one or more embodiments of the disclosure, an electronic device comprising: a display device comprising a substrate comprising a display area, and a non-display area around the display area; a passivation layer above the substrate; a light-emitting element above the passivation layer; a pixel-defining layer above the passivation layer in the display area and the non-display area, and comprising: a first inorganic layer above the substrate, a second inorganic layer above the first inorganic layer, and a third inorganic layer above the second inorganic layer, in the display area; and the first inorganic layer and the second inorganic layer, in the non-display area; a first bank above the pixel-defining layer; and a second bank above the first bank, and extending further than a side of the first bank.

The aspects according to the embodiments of the present disclosure are not limited to those mentioned above, and more various aspects are included in the following description of the present disclosure.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating that the display device of FIG. 1 is folded and viewed from the front;

FIG. 3 is a cross-sectional view illustrating that the display device of FIG. 1 is folded and viewed from the side;

FIG. 4 is an enlarged plan view illustrating an area A1 of FIG. 2;

FIG. 5 is a cross-sectional view illustrating a portion of a display device according to one or more embodiments;

FIG. 6 is an enlarged cross-sectional view illustrating an area A3 of FIG. 5;

FIG. 7 is an enlarged cross-sectional view illustrating an area A2 of FIG. 2;

FIGS. 8 to 11 are cross-sectional views illustrating a portion of a display device according to one or more embodiments; and

FIG. 12 is an enlarged cross-sectional view illustrating an area A5 of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

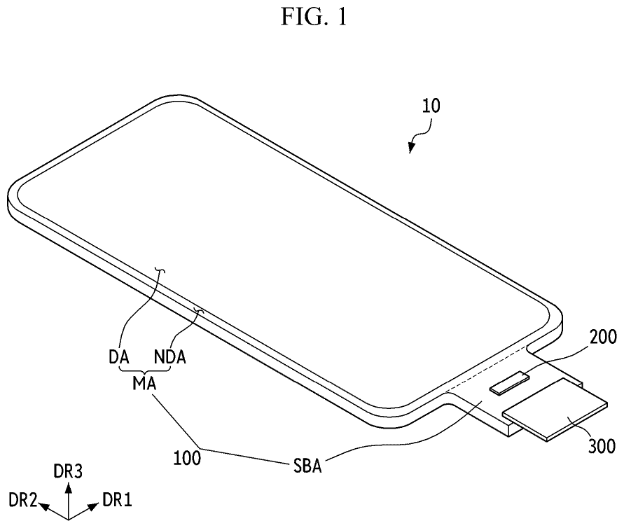

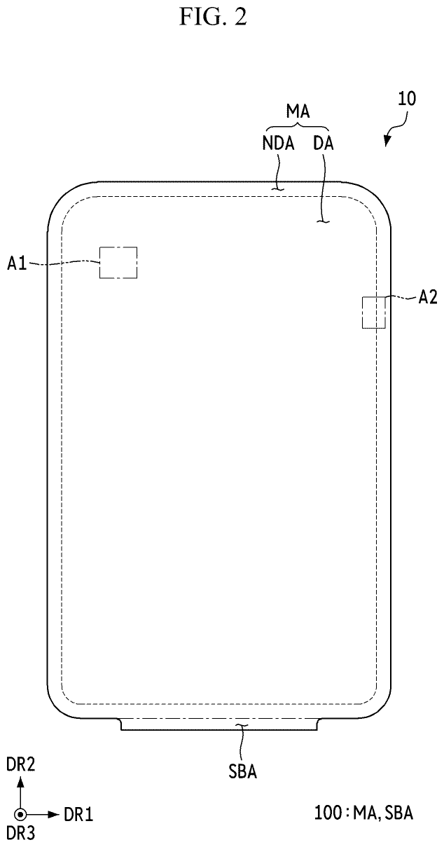

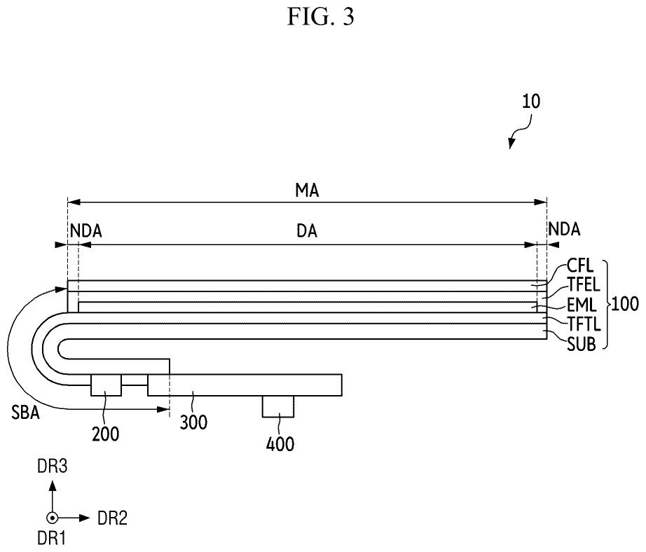

FIG. 1 is a perspective view illustrating a display device according to one or more embodiments. FIG. 2 is a plan view illustrating that the display device of FIG. 1 is folded and viewed from the front. FIG. 3 is a cross-sectional view illustrating that the display device of FIG. 1 is folded and viewed from the side.

Referring to FIG. 1, a display device 10 according to one or more embodiments The display device 10 may be used as an electronic device. An electronic device including the display device 10 may include the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), a television, a notebook, a monitor, a billboard and the Internet of Things (IoT). Those listed-above are merely as examples, and the display device 10 may be employed in other electronic devices as well.

The display device 10 according to one or more embodiments may be a light-emitting display device, such as an organic light-emitting display device using an organic light-emitting diode, a quantum dot light-emitting display device including a quantum dot light-emitting layer, an inorganic light-emitting display device including an inorganic semiconductor, and a micro or nano light-emitting display device including a micro or nano light-emitting diode (micro or nano LED). The following description will be based on that the display device 10 is an organic light-emitting display device, but the present disclosure is not limited thereto.

The display device 10 according to one or more embodiments may include a display panel 100, a display driver 200, and a circuit board 300.

The display panel 100 may be formed in a rectangular plane having a short side in a first direction DR1, and a long side in a second direction DR2 crossing the first direction DR1. A corner where the short side in the first direction DR1 and the long side in the second direction DR2 meet may be formed at a right angle, or may be rounded to have a curvature. A planar shape of the display panel 100 is not limited to the rectangular shape, and may be formed in another polygon, circle or ellipse.

The display panel 100 may be substantially flat, but is not limited thereto. For example, the display panel 100 may include a curved portion formed at left and right ends, having a constant curvature or a variable curvature. In addition, the display panel 100 may be flexibly formed to be curved, twisted, bent, folded or rolled.

The display panel 100 may include a main area MA and a sub area SBA.

The main area MA may include a display area DA for displaying an image, and a non-display area NDA for not displaying an image.

The display area DA may occupy most of areas of the display panel 100. The display area DA may be located at the center of the display panel 100. Pixels including a plurality of light emission areas, respectively, may be located in the display area DA to display an image.

The non-display area NDA may be adjacent to the display area DA. The non-display area NDA may be an outer area of the display area DA, and may surround the display area DA (e.g., in plan view). The non-display area NDA may be an edge area of the display panel 100. The area A2 of FIG. 2 relates to an edge area of the display device 10, and may include a portion of the display area DA and a portion of the non-display area NDA.

The sub-area SBA may be an area extended from one side of the main area MA. The sub-area SBA may include a flexible material capable of being subjected to bending, folding, rolling, and the like. For example, when the sub-area SBA is bent, the sub-area SBA may overlap the main area MA in a thickness direction (a third direction DR3). The sub-area SBA may include a display driver 200 and a pad area connected to the circuit board 300. In one or more other embodiments, the sub-area SBA may be omitted, and the display driver 200 and the pad area may be located in the non-display area NDA.

Referring to FIG. 1, the sub-area SBA may include a display pad PD, a display driver 200, and a circuit board 300.

The display pads PD may be located on one edge of the display panel 100. For example, the display pads PD may be located on a lower edge of the display panel 100. The display pads PD may be connected to the display driver 200 and the circuit board 300.

The display drivers 200 may generate and output signals and voltages for driving the display panel 100. In detail, the display drivers 200 may generate and output data voltages, power voltages, scan-timing signals, and the like. The display drivers 200 may supply a power voltage to a power line, and may supply a gate control signal to a gate driver.

The display drivers 200 may be located between the display pads PD and the display area DA in the non-display area NDA. The display drivers 200 may be attached to the non-display area NDA of the display panel 100 in a chip-on-glass (COG) method. Alternatively, the display drivers 200 may be attached to the circuit board 300 in a chip-on-plastic (COP) method.

The circuit boards 300 may be located on one edge of the display panel 100, and may be located on the display pads PD. The circuit boards 300 may be attached to the display pads PD by using a conductive adhesive member, such as an anisotropic conductive film and an anisotropic conductive adhesive. Therefore, the circuit boards 300 may be electrically connected to signal lines of the display panel 100. The circuit boards 300 may be a flexible printed circuit board or a flexible film, such as a chip-on film.

FIG. 3 is a cross-sectional view illustrating that the display device of FIG. 1 is folded and viewed from the side.

Referring to FIG. 3, the display panel 100 may include a substrate SUB, a thin film transistor layer TFTL, a light-emitting element layer EML, a thin film encapsulation layer TFEL, and a color filter layer CFL.

The substrate SUB may be a base substrate or a base member. The substrate SUB may be a flexible substrate capable of being subjected to bending, folding, rolling and the like. For example, the substrate SUB may include a polymer resin, such as polyimide (PI), but is not limited thereto. In one or more other embodiments, the substrate SUB may include a glass material or a metal material.

The thin film transistor layer TFTL may be located on the substrate SUB (as used herein, “located on” may mean “above”). The thin film transistor layer TFTL may include a plurality of thin film transistors constituting a pixel circuit of pixels. The thin film transistor layer TFTL may further include scan lines, data lines, power lines, scan control lines, fan-out lines connecting the display driver 200 with the data lines, and lead lines connecting the display driver 200 with the pad area. Each of the thin film transistors may include a semiconductor area, a source electrode, a drain electrode, and a gate electrode. For example, when the scan driver is formed on one side of the non-display area NDA of the display panel 100, the scan driver may include thin film transistors.

The thin film transistor layer TFTL may be located in the display area DA, the non-display area NDA, and the sub-area SBA. The thin film transistors, the scan lines, the data lines, and the power lines of the pixels of the thin film transistor layer TFTL may be located in the display area DA. The scan control lines and the fan-out lines of the thin film transistor layer TFTL may be located in the non-display area NDA. The lead lines of the thin film transistor layer TFTL may be located in the sub-area SBA.

The light-emitting element layer EML may be located on the thin film transistor layer TFTL. The light-emitting element layer EML may include a plurality of light-emitting elements, which include a first electrode, a second electrode, and a light-emitting layer to emit light, and a pixel-defining layer defining pixels. The plurality of light-emitting elements of the light-emitting element layer EML may be located in the display area DA.

In one or more embodiments, the light-emitting layer may be an organic light-emitting layer including an organic material. The light-emitting layer may include a hole-transporting layer, an organic light-emitting layer and an electron-transporting layer. When the first electrode receives a voltage through the thin film transistor of the thin film transistor layer TFTL, and the second electrode receives a cathode voltage, holes and electrons may be moved to the organic light-emitting layer through the hole-transporting layer and the electron-transporting layer, respectively, and may be combined with each other in the organic light-emitting layer to emit light.

In one or more other embodiments, the light-emitting element may include a quantum dot light-emitting diode including a quantum dot light-emitting layer, an inorganic light-emitting diode including an inorganic semiconductor, or a micro light-emitting diode.

The thin film encapsulation layer TFEL may cover an upper surface and sides of the light-emitting element layer EML, and may protect the light-emitting element layer EML. The thin film encapsulation layer TFEL may include at least one inorganic layer and at least one organic layer, which are intended to encapsulate the light-emitting element layer EML.

The color filter layer CFL may be located on the thin film encapsulation layer TFEL. The color filter layer CFL may include a plurality of color filters respectively corresponding to the plurality of light emission areas. Each of the color filters may selectively transmit light of a corresponding wavelength(s), and may block or absorb light of other wavelengths. The color filter layer CFL may absorb a portion of light incident from the outside of the display device 10 to reduce reflective light due to external light. Therefore, the color filter layer CFL may reduce or prevent distortion of a color due to external light reflection from occurring.

As the color filter layer CFL is directly located on the thin film encapsulation layer TFEL, the display device 10 may not require a separate substrate for the color filter layer CFL. Therefore, the display device 10 may be relatively thin.

In some embodiments, the display device 10 may further include an optical device. The optical device may emit or receive light of an infrared, ultraviolet, or visible band. For example, the optical device may be an optical sensor for sensing light incident on the display device 10, such as a proximity sensor, an illuminance sensor, a camera sensor, a fingerprint sensor, or an image sensor.

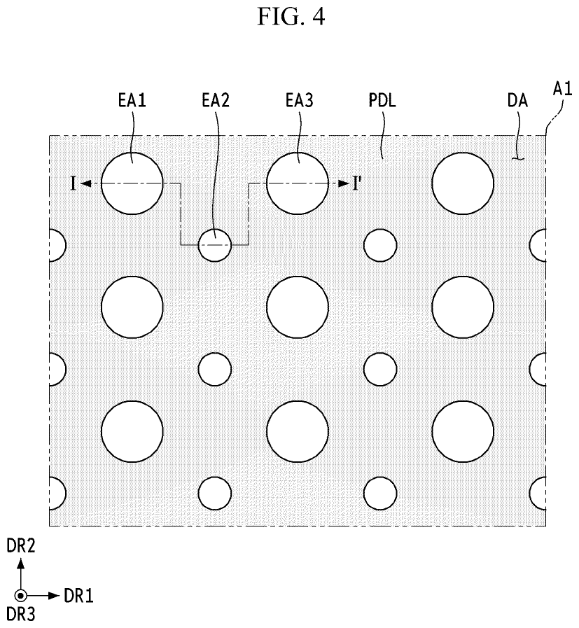

FIG. 4 is an enlarged plan view illustrating a portion of a display device according to one or more embodiments, for example, an area A1 of FIG. 2. FIG. 4 may be a layout view illustrating arrangement of the light emission areas EA1, EA2, and EA3 and the pixel-defining layer PDL in the display area DA.

Referring to FIG. 4, the pixel-defining layer PDL may cover the display area DA, and may expose the light emission areas EA1, EA2, and EA3. The pixel-defining layer PDL may define the light emission areas EA1, EA2, and EA3. In the drawing, the light emission areas EA1, EA2, and EA3 have circular shapes, but may be polygons, such as triangles, squares or hexagons. The plurality of light emission areas EA1, EA2, and EA3 may be located in a Pentile™ type, for example, a diamond Pentile™ type (Pentile™ being a registered trademark of Samsung Display Co., Ltd., Republic of Korea). For example, the first light emission area EA1 and the third light emission area EA3 may be spaced apart from each other in the first direction DR1, and may be alternately located in the first direction DR1 and the second direction DR2. The second light emission area EA2 may be spaced apart from another adjacent second light emission area EA2 in the first direction DR1 and the second direction DR2. The second light emission area EA2 and the first light emission area EA1, or the second light emission area EA2 and the third light emission area EA3, may be alternately located along any one direction in a plane defined by the first direction DR1 and the second direction DR2. The shape and arrangement of the plurality of light emission areas are not limited to FIG. 4.

The first to third light emission areas EA1, EA2, and EA3 may have different sizes. For example, the size of the first light emission area EA1 may be larger than that of the second light emission area EA2, and the size of the second light emission area EA2 may be smaller than that of the third light emission area EA3. The intensity of light emitted from the corresponding light emission areas EA1, EA2, and EA3 may vary depending on the sizes of the light emission areas EA1, EA2, and EA3, and a color of a screen displayed by the display device 10 may be controlled by adjusting the sizes of the light emission areas EA1, EA2, and EA3.

In the display device 10, one first light emission area EA1, one second light emission area EA2, and one third light emission area EA3, which are adjacent to one another, may form one pixel group. One pixel group may include light emission areas EA1, EA2, and EA3, which emit light of different colors, to represent a white gray scale, but the present disclosure is not limited thereto. Various modifications may be made in combination of the light emission areas EA1, EA2, and EA3 constituting one pixel group depending on the arrangement of the light emission areas EA1, EA2, and EA3, the color of light emitted from the light emission areas EA1, EA2, and EA3, and the like.

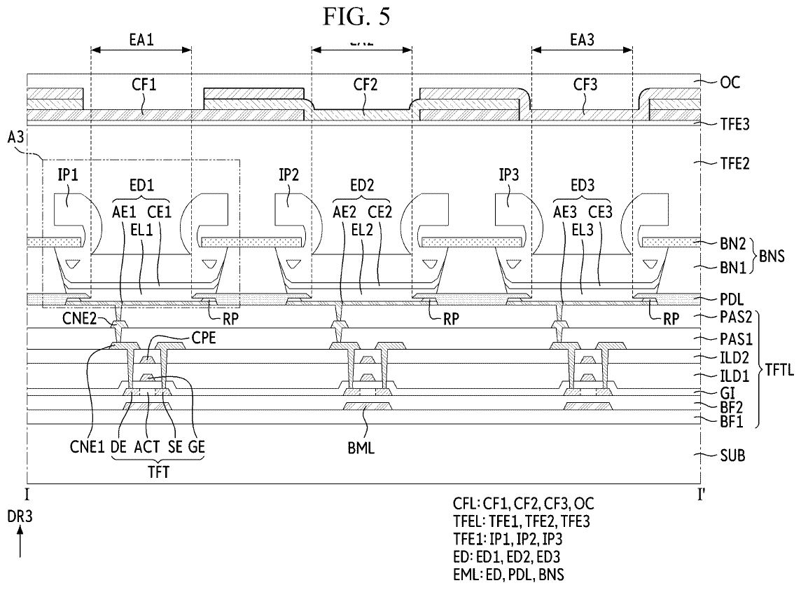

FIG. 5 is a cross-sectional view illustrating a portion of a display device according to one or more embodiments. In detail, FIG. 5 is a cross-sectional view taken along the line I-I′ of FIG. 4, illustrating a substrate SUB, a thin film transistor layer TFTL, a light-emitting element layer EML, a thin film encapsulation layer TFEL, and a color filter layer CFL.

The thin film transistor layer TFTL may include a first buffer layer BF1, a second buffer layer BF2, a thin film transistor TFT, a gate-insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be located on the substrate SUB. The first buffer layer BF1 may include an inorganic layer capable of reducing or preventing permeation of the air or moisture. For example, the first buffer layer BF1 may include a plurality of inorganic layers that are alternately stacked.

The lower metal layer BML may be located on the first buffer layer BF1. For example, the lower metal layer BML may be formed of a single layer or multi-layer made of any one of molybdenum (Mo), aluminum (Al), chromium (Cr), gold (Au), titanium (Ti), nickel (Ni), neodymium (Nd), and/or copper (Cu) or their alloy.

The second buffer layer BF2 may cover the first buffer layer BF1 and the lower metal layer BML. The second buffer layer BF2 may include an inorganic layer capable of reducing or preventing permeation of the air or moisture. For example, the second buffer layer BF2 may include a plurality of inorganic layers that are alternately stacked.

The thin film transistor TFT may be located on the second buffer layer BF2, and may constitute a pixel circuit of each of a plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the gate electrode GE in the thickness direction DR3, and may be insulated from the gate electrode GE by the gate-insulating layer GI. A portion of the semiconductor layer ACT may form the source electrode SE and the drain electrode DE by conductorizing a material of the semiconductor layer ACT.

The gate electrode GE may be located on the gate-insulating layer GI. The gate electrode GE may overlap the semiconductor layer ACT in the thickness direction DR3 with the gate-insulating layer GI interposed therebetween.

The gate-insulating layer GI may be located on the semiconductor layer ACT. For example, the gate-insulating layer GI may cover the semiconductor layer ACT and the second buffer layer BF2, and may insulate the semiconductor layer ACT from the gate electrode GE. The gate-insulating layer GI may include a contact hole through which the first connection electrode CNE1 passes.

The first interlayer insulating layer ILD1 may cover the gate electrode GE and the gate-insulating layer GI. The first interlayer insulating layer ILD1 may include a contact hole through which the first connection electrode CNE1 passes. The contact hole of the first interlayer insulating layer ILD1 may be connected to the contact hole of the gate-insulating layer GI and to a contact hole of the second interlayer insulating layer ILD2.

The capacitor electrode CPE may be located on the first interlayer insulating layer ILD1. The capacitor electrode CPE may overlap the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and to the contact hole of the gate-insulating layer GI.

The first connection electrode CNE1 may be located on the second interlayer insulating layer ILD2. The first connection electrode CNE1 may electrically connect the drain electrode DE of the thin film transistor TFT with pixel electrodes AE1, AE2, and AE3. The first connection electrode CNE1 may be inserted into the contact holes formed in the second interlayer insulating layer ILD2, the first interlayer insulating layer ILD1, and the gate-insulating layer GI to contact the drain electrode DE of the thin film transistor TFT.

The first passivation layer PAS1 may cover the first connection electrode CNE1 and the second interlayer dielectric layer ILD2. The first passivation layer PAS1 may protect the thin film transistor TFT. The first passivation layer PAS1 may include a contact hole through which the second connection electrode CNE2 passes. In one or more embodiments, the first passivation layer PAS1 may be formed of an organic layer, such as an acrylic resin, an epoxy resin, a phenolic resin, a polyamide resin, and/or a polyimide resin. Alternatively, the first passivation layer PAS1 may be formed of an inorganic layer, for example, a silicon nitride layer, a silicon oxynitride layer, a silicon oxide layer, a titanium oxide layer, or an aluminum oxide layer. Alternatively, the first passivation layer PAS1 may be formed of a plurality of layers of the organic or inorganic material described above.

The second connection electrode CNE2 may be located on the first passivation layer PAS1. The second connection electrode CNE2 may electrically connect the first connection electrode CNE1 with the pixel electrodes AE1, AE2, and AE3 of the light-emitting element ED. The second connection electrode CNE2 may be inserted into the contact hole formed in the first passivation layer PAS1 to contact the first connection electrode CNE1.

The second passivation layer PAS2 may cover the second connection electrode CNE2 and the first passivation layer PAS1. The second passivation layer PAS2 may compensate for a step difference caused by the thin film transistor TFT and metal lines, and may have a flat top surface. The second passivation layer PAS2 may include a contact hole through which the pixel electrodes AE1, AE2, and AE3 of the light-emitting element ED pass. In one or more embodiments, the second passivation layer PAS2 may be formed of an organic layer, such as an acrylic resin, an epoxy resin, a phenolic resin, a polyamide resin, and/or a polyimide resin.

The light-emitting element layer EML may be located on the thin film transistor layer TFTL. The light-emitting element layer EML may include a light-emitting element ED, a pixel-defining layer PDL, and a bank structure BNS. The light-emitting element ED may include pixel electrodes AE1, AE2, and AE3, light-emitting layers EL1, EL2, and EL3 and common electrodes CE1, CE2, and CE3.

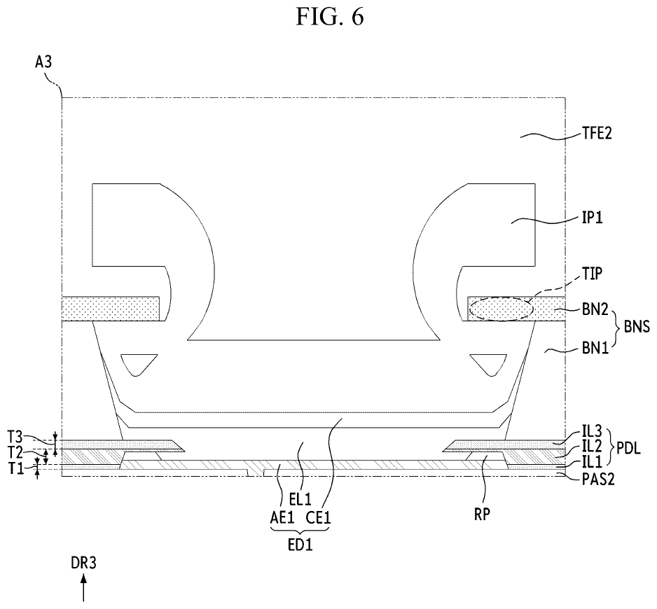

FIG. 6 is an enlarged cross-sectional view of an area A3 of FIG. 5, illustrating the first light emission area EA1 and the periphery thereof in detail. Hereinafter, the light-emitting element layer EML will be described with respect to the first light emission area by way of example.

Referring to FIGS. 5 and 6, the display device 10 may include a plurality of light emission areas EA1, EA2, and EA3 located in the display area DA, and a non-light emission area located between the light emission areas EA1, EA2, and EA3. The light emission areas EA1, EA2, and EA3 may be defined as areas where the pixel electrodes AE1, AE2, and AE3, the light-emitting layers EL1, EL2, and EL3, and the common electrodes CE1, CE2, and CE3 respectively overlap in the thickness direction of the substrate SUB. The light emission areas EA1, EA2, and EA3 may include a first light emission area EA1, a second light emission area EA2, and a third light emission area EA3, which are spaced apart from one another, and may emit light of the same color or different colors. In one or more embodiments, the first light emission area EA1 may emit light of a first color, the second light emission area EA2 may emit light of a second color, and the third light emission area EA3 may emit light of a third color.

The display device 10 may include a plurality of light-emitting elements ED1, ED2, and ED3 respectively located in different light emission areas EA1, EA2, and EA3. The light-emitting elements ED1, ED2, and ED3 may include a first light-emitting element ED1 located in the first light emission area EA1, a second light-emitting element ED2 located in the second light emission area EA2, and a third light-emitting element ED3 located in the third light emission area EA3.

The light-emitting elements ED1, ED2, and ED3 may include pixel electrodes AE1, AE2, and AE3, light-emitting layers EL1, EL2, and EL3, and common electrodes CE1, CE2, and CE3, respectively, and the light-emitting elements ED1, ED2, and ED3 respectively located in the different light emission areas EA1, EA2, and EA3 may emit light of different respective colors depending on materials of the light-emitting layers EL1, EL2, and EL3. For example, the first light-emitting element ED1 located in the first light emission area EA1 may emit first light of a red color, which has a peak wavelength in the range of about 610 nm to about 650 nm, the second light-emitting element ED2 located in the second light emission area EA2 may emit second light of a green color, which has a peak wavelength in the range of about 510 nm to about 550 nm, and the third light-emitting element ED3 located in the third light emission area EA3 may emit third light of a blue color, which has a peak wavelength in the range of about 440 nm to about 480 nm. The first to third light emission areas EA1, EA2, and EA3 constituting one pixel may include the light-emitting elements ED1, ED2, and ED3 for emitting light of different colors to represent a white gray scale. Alternatively, as the light-emitting layers EL1, EL2, and EL3 may include two or more materials for emitting light of different colors, one light-emitting layer may emit mixture light. For example, the light-emitting layers EL1, EL2, and EL3 may include a material for emitting red light and a material for emitting green light together to emit yellow light, or may include all of a material for emitting red light, a material for emitting green light, and a material for emitting blue light to emit white light.

The pixel electrodes AE1, AE2, and AE3 may be located on the second passivation layer PAS2. The pixel electrodes AE1, AE2, and AE3 may be located in the plurality of light emission areas EA1, EA2, and EA3, respectively. The pixel electrodes AE1, AE2, and AE3 may include a first pixel electrode AE1 located in the first light emission area EA1, a second pixel electrode AE2 located in the second light emission area EA2, and a third pixel electrode AE3 located in the third light emission area EA3. The first pixel electrode AE1, the second pixel electrode AE2, and the third pixel electrode AE3 may be spaced apart from one another on the second passivation layer PAS2.

The pixel electrodes AE1, AE2, and AE3 may be electrically connected to a corresponding drain electrode DE of a thin film transistor TFT through a first connection electrodes CNE1. Edges of the spaced pixel electrodes AE1, AE2, and AE3 may be covered by the pixel-defining layer PDL, so that the first to third pixel electrodes AE1, AE2, and AE3 may be insulated from one another.

The pixel electrodes AE1, AE2, and AE3 may include a transparent electrode material and/or a conductive metal material, and may have a single-layered structure or a multi-layered structure. The metal material may be one or more of silver (Ag), copper (Cu), aluminum (Al), nickel (Ni), lanthanum (La), titanium (Ti), or titanium nitride (TiN). The transparent electrode material may be one or more of Indium Tin Oxide (ITO), Indium Zinc Oxide (IZO), or Indium Tin Zinc Oxide (ITZO). In one or more embodiments, the pixel electrodes AE1, AE2, and AE3 may have a multi-layered structure that includes a metal material layer and a transparent electrode material layer.

The light-emitting layers EL1, EL2, and EL3 may be located on the pixel electrodes AE1, AE2, and AE3. The light-emitting layers EL1, EL2, and EL3 may be organic light-emitting layers made of an organic material, and may be formed on the pixel electrodes AE1, AE2, and AE3 through a deposition process. The light-emitting layers EL1, EL2, and EL3 may have a multi-layered structure, and each of a hole injection material, a hole-transporting material, a light-emitting material, an electron-transporting material and/or an electron injection material may constitute a layer. When the thin film transistor TFT applies a voltage (e.g., predetermined voltage) to the pixel electrodes AE1, AE2, and AE3 of the light-emitting elements ED1, ED2, and ED3 and the common electrodes CE1, CE2, and CE3 of the light-emitting elements ED1, ED2, and ED3 receive a common voltage or a cathode voltage, holes and electrons may be injected and transported, and may be combined with each other in the light-emitting layers EL1, EL2, and EL3 to emit light.

The light-emitting layers EL1, EL2, and EL3 may include a first light-emitting layer EL1, a second light-emitting layer EL2, and a third light-emitting layer EL3, which are located in the different light emission areas EA1, EA2, and EA3, respectively. The first light-emitting layer EL1 may be located on the first pixel electrode AE1 in the first light emission area EA1, the second light-emitting layer EL2 may be located on the second pixel electrode AE2 in the second light emission area EA2, and the third light-emitting layer EL3 may be located on the third pixel electrode AE3 in the third light emission area EA3. The plurality of light-emitting layers EL1, EL2, and EL3 may emit light of different colors, respectively, or one of the light-emitting layers EL1, EL2, and EL3 may emit mixture light. In one or more embodiments, the first light-emitting layer EL1 may emit red light, the second light-emitting layer EL2 may emit green light, and the third light-emitting layer EL3 may emit blue light.

The light-emitting layers EL1, EL2, and EL3 may be located on an upper surface of the pixel-defining layer PDL. In one or more embodiments, a side of a residual pattern RP may be more recessed than that of the pixel-defining layer PDL, and a portion of the light-emitting layers EL1, EL2, and EL3 may be located in spaces between the pixel electrodes AE1, AE2, and AE3 and the pixel-defining layer PDL. In one or more embodiments, the light-emitting layers EL1, EL2, and EL3 may contact the pixel-defining layer PDL, the residual pattern RP, and the pixel electrodes AE1, AE2, and AE3.

The common electrodes CE1, CE2, and CE3 may be located on the light-emitting layers EL1, EL2, and EL3. The common electrodes CE1, CE2, and CE3 may include a transparent conductive material so that light generated from the light-emitting layers EL1, EL2, and EL3 may be emitted. The common electrodes CE1, CE2, and CE3 may receive a common voltage or a low potential voltage. When the pixel electrodes AE1, AE2, and AE3 receive a voltage corresponding to the data voltage and the common electrodes CE1, CE2, and CE3 receive a low potential voltage, a potential difference may be formed between the pixel electrodes AE1, AE2, and AE3 and the common electrodes CE1, CE2, and CE3, whereby the light-emitting layers EL1, EL2, and EL3 may emit light.

The common electrodes CE1, CE2, and CE3 may include a first common electrode CE1, a second common electrode CE2, and a third common electrode CE3, which are located in the different light emission areas EA1, EA2, and EA3, respectively. The first common electrode CE1 may be located on the first light-emitting layer EL1 in the first light emission area EA1, the second common electrode CE2 may be located on the second light-emitting layer EL2 in the second light emission area EA2, and the third common electrode CE3 may be located on the third light-emitting layer EL3 in the third light emission area EA3. The first to third common electrodes CE1, CE2, and CE3 may be spaced apart from one another.

In one or more embodiments, a capping layer may be selectively located on the common electrodes CE1, CE2, and CE3. The capping layer may include an organic material or an inorganic insulating material to cover patterns located on the light-emitting elements ED1, ED2, and ED3. The capping layer may reduce or prevent damage of the light-emitting elements ED1, ED2, and ED3 due to the external air. In one or more embodiments, the capping layer may include an organic material, such as a-NPD, NPB, TPD, m-MTDATA, Alq₃, LiF, and/or CuPc or an inorganic material, such as aluminum oxide, titanium oxide, tantalum oxide, hafnium oxide, zinc oxide, silicon oxide, silicon nitride, and/or silicon oxynitride.

The capping layer may include a first capping layer, a second capping layer, and a third capping layer, which are located in the different light emission areas EA1, EA2, and EA3, respectively. The first to third capping layers may be spaced apart from one another.

The pixel-defining layer PDL may be located on the second passivation layer PAS2 to expose the upper surfaces of the pixel electrodes AE1, AE2, and AE3.

The pixel-defining layer PDL may include a first inorganic layer IL1 located on the second passivation layer PAS2, a second inorganic layer IL2 located on the first inorganic layer IL1, and a third inorganic layer IL3 located on the second inorganic layer IL2. The first inorganic layer IL1 may absorb moisture from the second passivation layer PAS2, the second inorganic layer IL2 may protect the first inorganic layer IL1, and the third inorganic layer IL3 may reduce or prevent moisture permeation.

The first to third inorganic layers IL1, IL2, and IL3 of the pixel-defining layer PDL may include an inorganic insulating material. The pixel-defining layer PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, or an amorphous silicon layer, but is not limited thereto.

The first inorganic layer IL1 and the second inorganic layer IL2, which are adjacent to each other, may include different materials, and thus may have different etching rates with respect to an etchant. The second inorganic layer IL2 and the third inorganic layer IL3, which are adjacent to each other, may include different materials and thus may have different etching rates with respect to an etchant. In one or more embodiments, the first inorganic layer IL1 and the third inorganic layer IL3 may include the same material or different materials.

In one or more embodiments, the first inorganic layer IL1 and the third inorganic layer IL3 may include silicon nitride (SiNx), and the second inorganic layer IL2 may include one or more of silicon oxynitride (SiOxNy) or silicon oxide (SiOx).

A thickness of the first inorganic layer IL1 may be less than that of the second inorganic layer IL2. The thickness T1 of the first inorganic layer IL1 may be less than that of the pixel electrodes AE1, AE2, and AE3. The thickness of the second inorganic layer IL1 may be greater than that of the third inorganic layer IL3. In one or more embodiments, the thickness of the first inorganic layer IL1 may be about 200 Å to about 1000 Å, or about 500 Å to about 1000 Å. In one or more embodiments, the thickness of the second inorganic layer IL2 may be about 1000 Å to about 3000 Å, or about 1500 Å to about 2500 Å.

According to one or more embodiments, the pixel-defining layer PDL is located on the edges of the pixel electrodes AE1, AE2, and AE3, and may be spaced apart from the upper surfaces of the pixel electrodes AE1, AE2, and AE3. The pixel-defining layer PDL might not directly contact the upper surfaces of the pixel electrodes AE1, AE2, and AE3 while partially overlapping the upper surfaces of the pixel electrodes AE1, AE2, and AE3 in the thickness direction DR3 of the substrate SUB, and the residual pattern RP may be located between the pixel-defining layer PDL and the pixel electrodes AE1, AE2, and AE3. However, the pixel-defining layer PDL may direly contact the sides of the pixel electrode AE1, AE2, and AE3.

The second inorganic layer IL2 may include a first side facing the sides of the pixel electrodes AE1, AE2, and AE3, a second side more protruded toward the light emission areas EA1, EA2, and EA3 than the first side, and a first lower surface connecting the first side with the second side. The first lower surface of the second inorganic layer IL2 may face an upper surface of the residual pattern RP, and the first side may face a side of the residual pattern RP. The second side of the second inorganic layer IL2 may define the light emission areas EA1, EA2, and EA3. The pixel electrodes AE1, AE2, and AE3 may overlap the second inorganic layer IL2 and/or the third inorganic layer IL3 in the thickness direction DR3, and might not overlap the first inorganic layer IL1.

The residual pattern RP may be located on the edge of each of the pixel electrodes AE1, AE2, and AE3. The pixel-defining layer PDL may not directly contact the upper surfaces of the pixel electrodes AE1, AE2, and AE3 due to the residual pattern RP. In a manufacturing process of the display device 10, a portion of a sacrificial layer located on the pixel electrodes AE1, AE2, and AE3 may be removed so that the residual pattern RP may be formed. The residual pattern RP may include a metal or an oxide semiconductor material. In the drawing, the side of the residual pattern RP, which is directed toward the light emission areas EA1, EA2, and EA3, is only illustrated as being more recessed than the second side of the pixel-defining layer PDL, but the present disclosure is not limited thereto. The side of the residual pattern RP may protrude further than the second side of the pixel-defining layer PDL toward the light emission areas EA1, EA2, and EA3, or may be aligned with the second side of the pixel-defining layer PDL.

The display device 10 may include a bank structure BNS located on the pixel-defining layer PDL. The bank structure BNS may have a structure in which banks BN1 and BN2, which include different respective materials, are sequentially stacked, and may include/define a plurality of openings that overlap the light emission areas EA1, EA2, and EA3. The bank structure BNS may overlap the non-light emission area located among the light emission areas EA1, EA2, and EA3, and may overlap a light-blocking area of the color filters CF1, CF2, and CF3, which will be described later.

The first bank BN1 may be located on the pixel-defining layer PDL. A side of the first bank BN1 may be more recessed than that of the pixel-defining layer PDL in an opposite direction of a direction toward the light emission areas EA1, EA2, and EA3. The side of the first bank BN1 may be more recessed than that of the second bank BN2, which will be described later, in the opposite direction of the direction directed toward the light emission areas EA1, EA2, and EA3.

According to one or more embodiments, the first bank BN1 may include a metal material. In one or more embodiments, the first bank BN1 may include aluminum (Al), an oxide of aluminum (Al), or an alloy of aluminum (Al).

The common electrode CE1, CE2, and CE3 may directly contact the side of the first bank BN1. Ends of the common electrodes CE1, CE2, and CE3 may contact the side(s) of the first bank BN1. The common electrodes CE1, CE2, and CE3 of the spaced light-emitting elements ED1, ED2, and ED3 may directly contact the first bank BN1, and the first bank BN1 may include a conductive material so that the common electrodes CE1, CE2, and CE3 may be electrically connected to one another through the first bank BN1.

According to one or more embodiments, the light-emitting layers EL1, EL2, and EL3 may directly contact the side of the first bank BN1. An area in which the common electrodes CE1, CE2, and CE3 contact the side of the first bank BN1 may be greater than an area in which the light-emitting layers EL1, EL2, and EL3 contact the side of the first bank BN1. The common electrodes CE1, CE2, and CE3 may be located on the side of the first bank BN1 to have an area larger than the light-emitting layers EL1, EL2, and EL3, and/or to have a higher position than the side of the first bank BN1. Because the common electrodes CE1, CE2, and CE3 of the different light-emitting elements ED1, ED2, and ED3 are electrically connected to one another through the first bank BN1, it may be suitable that the common electrodes CE1, CE2, and CE3 contact the first bank BN1 in more areas (e.g., that the common electrodes CE1, CE2, and CE3 have a greater contact area with the first bank BN1).

The first bank BN1 may have an upper surface at a higher position than the common electrodes CE1, CE2, and CE3. A height from the substrate SUB to the upper surface of the first bank BN1 may be greater than a height from the substrate SUB to the common electrodes CE1, CE2, and CE3.

The second bank BN2 may be located on the first bank BN1. The second bank BN2 may include/define openings that overlap the light emission areas EA1, EA2, and EA3, respectively, and each of the openings may include a side. The second bank BN2 may include a tip TIP or eave that is an area more protruded than the first bank BN1. The side of the second bank BN2 may protrude to a greater degree toward the light emission areas EA1, EA2, and EA3 than the side of the first bank BN1.

As the side of the second bank BN2 has a shape extending further toward the light emission areas EA1, EA2, and EA3 than the side of the first bank BN1, an undercut structure of the first bank BN1 may be formed below the tip TIP of the second bank BN2.

In the display device 10 according to one or more embodiments, the bank structure BNS may include a tip TIP protruded toward the light emission areas EA1, EA2, and EA3 so that the light-emitting layers EL1, EL2, and EL3 and the common electrodes CE1, CE2, and CE3, which are spaced apart from each other, may be formed by deposition and etching processes, as opposed to a mask process. Also, different layers may be individually formed in the different light emission areas EA1, EA2, and EA3 even through a deposition process. For example, although the light-emitting layers EL1, EL2, and EL3 of the light-emitting elements ED1, ED2, and ED3 and the common electrodes CE1, CE2, and CE3 are formed by the deposition process without using a mask, the deposited materials may be disconnected with the bank structure BNS interposed therebetween by the tip TIP of the second bank BN2 without being connected among the light emission areas EA1, EA2, and EA3. After a material for forming a corresponding layer is formed on an entire surface of the display device 10, different layers may be individually formed in the different light emission areas EA1, EA2, and EA3 through a process of removing a layer formed in an undesired area through etching. In the display device 10, the different light-emitting elements ED1, ED2, and ED3 may be respectively formed for the light emission areas EA1, EA2, and EA3 through deposition and etching processes without using a mask process, unnecessary elements in the display device 10 may be omitted, and a size of the non-display area NDA may be reduced or minimized.

The second bank BN2 may include a metal material different from the metal material of the first bank BN1. The metal material of the second bank BN2 is removed by dry etching together with the metal material of the first bank BN1, but with respect to wet etching, may be any material that has an etch rate significantly slower than that of the first bank BN1 or that is not to be etched. In one or more embodiments, the first bank BN1 may include aluminum (Al), an oxide of aluminum (Al), or an alloy of aluminum (Al), and the second bank BN2 may include titanium (Ti), an oxide of titanium (Ti), or an alloy of titanium (Ti).

The tip TIP of the second bank BN2 may overlap the common electrodes CE1, CE2, and CE3, the light-emitting layers EL1, EL2, and EL3, and the pixel-defining layer PDL in the direction DR3 that is normal to the substrate SUB. The common electrodes CE1, CE2, and CE3 may be formed below a lower surface of the tip TIP of the second bank BN2. Ends of each of the common electrodes CE1, CE2, and CE3 may overlap the second bank BN2 in the thickness direction DR3 of the substrate.

The thin film encapsulation layer TFEL (e.g., TFE1, TFE2, and TFE3, as shown in FIG. 5) may be located on the light-emitting elements ED1, ED2, and ED3 and the bank structure BNS, and may cover the plurality of light-emitting elements ED1, ED2, and ED3 and the bank structure BNS. The thin film encapsulation layer TFEL may include at least one inorganic layer to reduce or prevent permeation of oxygen or moisture into the light-emitting element layer EML. The thin film encapsulation layer TFEL may include at least one organic layer to protect the light-emitting element layer EML from particles, such as dust.

In one or more embodiments, the thin film encapsulation layer TFEL may include a lower inorganic encapsulation layer TFE1, an organic encapsulation layer TFE2, and an upper inorganic encapsulation layer TFE3, which are sequentially stacked.

Each of the lower inorganic encapsulation layer TFE1 and the upper inorganic encapsulation layer TFE3 may include one or more inorganic insulating materials. The inorganic insulating material may be any one of silicon oxide, silicon nitride and silicon oxynitride, and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy-based resin, polyimide, and/or polyethylene. For example, the organic encapsulation layer TFE2 may include an acrylic resin, for example, polymethyl methacrylate, polyacrylic acid, etc. The organic encapsulation layer TFE2 may be formed by hardening a monomer or coating a polymer.

The lower inorganic encapsulation layer TFE1 may be located on the light-emitting elements ED1, ED2, and ED3 and the bank structure BNS. The lower inorganic encapsulation layer TFE1 may include a first inorganic pattern IP1, a second inorganic pattern IP2, and a third inorganic pattern IP3, which respectively correspond to the different light emission areas EA1, EA2, and EA3. Each of the first inorganic pattern IP1, the second inorganic pattern IP2, and the third inorganic pattern IP3 may include an inorganic insulating material to respectively cover the light-emitting elements ED1, ED2, and ED3. The first inorganic pattern IP1, the second inorganic pattern IP2, and the third inorganic pattern IP3 may reduce or prevent damage to the light-emitting elements ED1, ED2, and ED3 due to the external air.

The lower inorganic encapsulation layers TFE1: IP1, IP2, and IP3 may be formed through a chemical vapor deposition (CVD) method, and thus may be formed along a step difference of the deposited layers. For example, the first inorganic pattern IP1, the second inorganic pattern IP2, and the third inorganic pattern IP3 may form a thin film even below an undercut due to the tip of the bank structure BNS. The lower inorganic encapsulation layers IP1, IP2, and IP3 may be located along the upper surface, the side and the lower surface of the second bank BN2, the side of the first bank BN1 and the upper surfaces of the common electrodes CE1, CE2, and CE3. For example, the lower inorganic encapsulation layers IP1, IP2, and IP3 may contact the lower surface of the second bank BN2 to reduce or prevent the likelihood of moisture permeation from the external air occurring.

The first inorganic pattern IP1 does not overlap the second light-emitting element ED2 and the third light-emitting element ED3, and may be located only on the first light-emitting element ED1 and the bank structure BNS near the first light-emitting element ED1. The second inorganic pattern IP2 does not overlap the first light-emitting element ED1 and the third light-emitting element ED3, and may be located only on the second light-emitting element ED2 and the bank structure BNS near the second light-emitting element ED2. The third inorganic pattern IP3 does not overlap the first light-emitting element ED1 and the second light-emitting element ED2, and may be located only on the third light-emitting element ED3 and the bank structure BNS near the third light-emitting element ED3.

The first inorganic pattern IP1 may be formed after the first common electrode CE1 is formed, the second inorganic pattern IP2 may be formed after the second common electrode CE2 is formed, and the third inorganic pattern IP3 may be formed after the third common electrode CE3 is formed. The first inorganic pattern IP1, the second inorganic pattern IP2, and the third inorganic pattern IP3 may be spaced apart from one another on the bank structure BNS.

The lower inorganic encapsulation layers IP1, IP2, and IP3 are located on the upper and lower surfaces of the light-emitting elements ED1, ED2 and ED and the second bank BN2 near the light-emitting elements ED1, ED2, and ED3, and may be spaced apart from the upper surface of the second bank BN2. That is, the lower inorganic encapsulation layers IP1, IP2, and IP3 may have an undercut structure on the second bank BN2. The space between the lower inorganic encapsulation layers IP1, IP2, and IP3 and the upper surface of the second bank BN2 may be a space from which materials of the light-emitting layers EL1, EL2, and EL3 and the common electrodes CE1, CE2, and CE3, which are deposited on the entire surface, are removed.

The organic encapsulation layer TFE2 is located on the bank structure BNS and the lower inorganic encapsulation layers IP1, IP2, and IP3. A portion of the organic encapsulation layer TFE2 may be located in the space between the lower inorganic encapsulation layers IP1, IP2, and IP3 and the upper surface of the second bank BN2. In the area where the second bank BN2 overlaps the lower inorganic encapsulation layers IP1, IP2, and IP3, the second bank BN2, the organic encapsulation layer TFE2 and the lower inorganic encapsulation layers IP1, IP2, and IP3 may be sequentially located. In the tip TIP area, the organic encapsulation layer TFE2 and the lower inorganic encapsulation layers IP1, IP2, and IP3 may be sequentially located on the second bank BN2, and the organic encapsulation layer TFE2 may be located again on the lower inorganic encapsulation layers IP1, IP2, and IP3. In other words, a portion of the organic encapsulation layer TFE2 may be located between the upper surface of the second bank BN2 and the lower inorganic encapsulation layers IP1, IP2, and IP3 on the tip TIP of the second bank BN2, and another portion thereof may be located on the lower inorganic encapsulation layers IP1, IP2, and IP3.

In one or more embodiments, the entire upper surface of the second bank BN2 may contact the organic encapsulation layer TFE2. A first lower surface of the lower inorganic encapsulation layers IP1, IP2, and IP3 may be a surface facing the upper surface of the second bank BN2, and the first lower surface of the lower inorganic encapsulation layers IP1, IP2, and IP3 may contact the organic encapsulation layer TFE2. The organic encapsulation layer TFE2 may contact the side of the second bank BN2.

The upper inorganic encapsulation layer TFE3 may be located on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The display device 10 may include a plurality of color filters CF1, CF2, and CF3 located on the light emission areas EA1, EA2, and EA3. Each of the plurality of color filters CF1, CF2, and CF3 may include a filtering pattern area and a light-blocking area. The filtering pattern area may overlap the light emission areas EA1, EA2, and EA3 or the openings of the bank structures BNS, and may form an emission area through which light emitted from the light emission areas EA1, EA2, and EA3 is emitted. The light-blocking area is an area in which a plurality of color filters CF1, CF2, and CF3 are stacked so that light cannot be transmitted, and may overlap the non-light emission area NEA.

The color filters CF1, CF2, and CF3 may include a first color filter CF1, a second color filter CF2, and a third color filter CF3, which correspond to the different light emission areas EA1, EA2, and EA3, respectively. The color filters CF1, CF2, and CF3 may include a colorant, such as a dye or pigment for absorbing light of another wavelength band other than light of a corresponding wavelength band, and may correspond to colors of the light emitted from the light emission areas EA1, EA2, and EA3. For example, the first color filter CF1 may be a red color filter overlapping the first light emission area EA1 for transmitting only first light of a red color. The second color filter CF2 may be a green color filter overlapping the second light emission area EA2 for transmitting only second light of a green color. The third color filter CF3 may be a blue color filter overlapping the third light emission area EA3 for transmitting only third light of a blue color.

As the color filters CF1, CF2, and CF3 overlap one another, the display device 10 may reduce the intensity of reflective light due to the external light. Furthermore, the display device 10 may control a color sense of the reflective light due to external light by adjusting a layout, a shape, an area, and the like of the color filters CF1, CF2, and CF3 on the plan view.

An overcoat layer OC may be located on the color filters CF1, CF2, and CF3 to planarize upper ends of the color filters CF1, CF2, and CF3. The overcoat layer OC may be a colorless light-transmissive layer having no color of a visible light band. For example, the overcoat layer OC may include a colorless light-transmissive organic material, such as an acrylic resin.

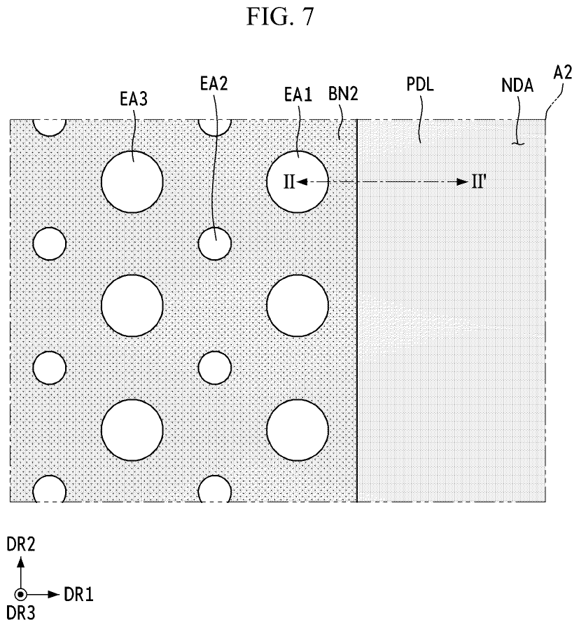

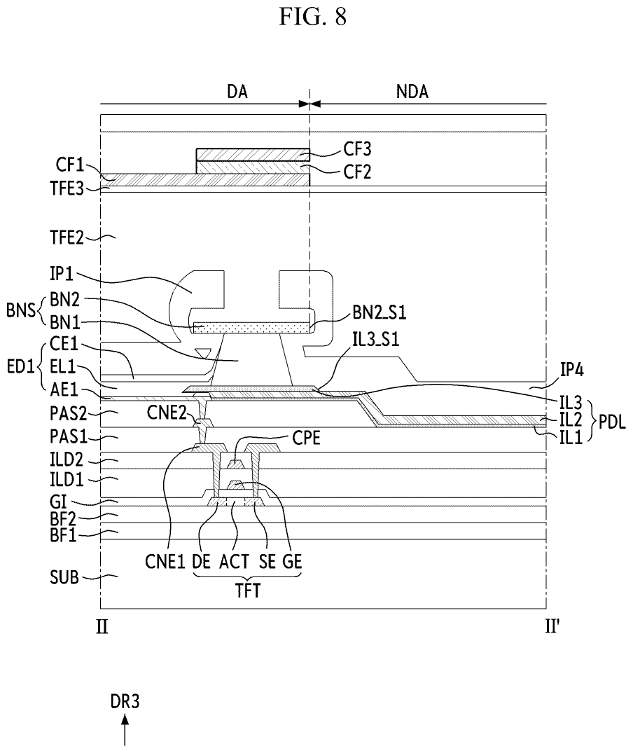

The non-display area NDA will be described in detail with reference to FIGS. 7 and 8.

FIG. 7 is an enlarged view illustrating an edge area of the display device 10, which is a boundary between a display area DA and a non-display area NDA of a display device. FIG. 7 is an enlarged plan view of an area A2 of FIG. 2, and FIG. 8 is a cross-sectional view taken along the line II-II′ of FIG. 7, illustrating an example of a display device.

Referring to FIGS. 7 and 8, the display device 10 includes a display area DA in which the bank structure BNS and the light-emitting element ED are located, and a non-display area NDA located near the display area DA. The bank structure BNS may be a boundary of the display area DA. The pixel-defining layer PDL may be located not only in the display area DA, but also in the non-display area NDA.

Meanwhile, light-emitting layers EL1, EL2, and EL3, common electrodes CE1, CE2, and CE3 and lower inorganic encapsulation layers IP1, IP2, and IP3 of the light-emitting elements ED1, ED2, and ED3 may be sequentially formed for each color. After materials of the first light-emitting layer EL1, the first common electrode CE1, and the first inorganic pattern IP1 of a first color are deposited or coated on an entire surface, the first light-emitting layer EL1, the first common electrode CE1, and the first inorganic pattern IP1 remain only in the first light emission area EA1 and in its peripheral area by patterning. Afterwards, the same process may be repeated for the second light-emitting layer EL2, the second common electrode CE2, and the second inorganic pattern IP2 of a second color so that the second light-emitting layer EL2, the second common electrode CE2, and the second inorganic pattern IP2 may be formed. A wet etching process or a cleaning process may be performed during the patterning process of the second color. When the second passivation layer PAS2, on which an organic material is formed on an entire surface, is exposed to a solution of the wet etching process or the cleaning process, the second passivation layer PAS2 of the organic layer may absorb moisture. As the first light-emitting layer EL1 includes the organic material, it may be difficult to dry moisture of the second passivation layer PAS2 through high-temperature baking during the patterning process of the second color. The remaining moisture may deteriorate reliability when the display device 10 is driven.

Referring to FIG. 8, the pixel-defining layer PDL may cover the second passivation layer PAS2. An upper surface and a side of the second passivation layer PAS2 are covered with the pixel electrodes AE1, AE2, and AE3 and the pixel-defining layer PDL, and a lower surface of the second passivation layer PAS2 is covered with the first passivation layer PAS1 therebelow, whereby moisture may be reduced or prevented from permeating into the second passivation layer PAS2.

The pixel-defining layer PDL may include a first to third inorganic layer IL1M IL2 and IL3. The third inorganic layer IL3 to expose the second inorganic layer IL2 having a different etchant selectivity even though the third inorganic layer IL3 at an upper portion is removed by an etchant during patterning for each color. The second inorganic layer IL2 is not etched by the etchant (etch stopper), and thus the second passivation layer PAS2 may be protected from the etchant.

The third inorganic layer IL3 of the pixel-defining layer PDL may be removed from at least a portion of the non-display area NDA. The third inorganic layer IL3 may include a first side IL3_S1 directed toward (e.g., facing) the non-display area NDA, and the second bank BN2 may include a first side BN2_S1 directed toward (e.g., facing) the non-display area NDA. The first side IL3_S1 of the third inorganic layer IL3 may be adjacent to the first side BN2_S1 of the second bank BN2. In one or more embodiments, the first side IL3_S1 of the third inorganic layer IL3 may be aligned with the first side BN2_S1 of the second bank BN2, or may protrude further than the first side BN2_S1 of the second bank BN2.

The second passivation layer PAS2 may include a side inclined from the substrate SUB in the non-display area NDA. An angle θ formed by the lower surface and the side of the second passivation layer PAS2 may be less than about 90°.

The pixel-defining layer PDL may include a first portion located at a position of a first height from the substrate SUB, a second portion located at a position of a second height from the substrate SUB, and a third portion located at a position of a third height from the substrate SUB. The first height may be greater than the second height, and the second height may be greater than the third height. The first portion, the second portion, and the third portion of the pixel-defining layer PDL may be sequentially located in a longitudinal direction of the substrate SUB. In other words, the second portion of the pixel-defining layer PDL may be located between the first portion and the third portion in the longitudinal direction of the substrate SUB. The height of the pixel-defining layer PDL refers to a vertical distance between the upper surface of the substrate SUB and a lower surface of a corresponding portion of the pixel-defining layer PDL.

A fourth inorganic pattern IP4 may be formed on the second inorganic layer IL2. The fourth inorganic pattern IP4 may be formed concurrently or substantially simultaneously with any one of the first to third inorganic patterns IP1, IP2, and/or IP3 of the lower inorganic encapsulation layer TFE1, and may include the same material as that of the first to third inorganic patterns IP1, IP2, and IP3. The fourth inorganic pattern IP4 may be spaced apart from one or more of the first to third inorganic patterns IP1, IP2, or IP3 of the lower inorganic encapsulation layer TFE1. The fourth inorganic pattern IP4 may be located on the second inorganic layer IL2, the first inorganic layer IL1, the first bank BN1, and the second bank BN2.

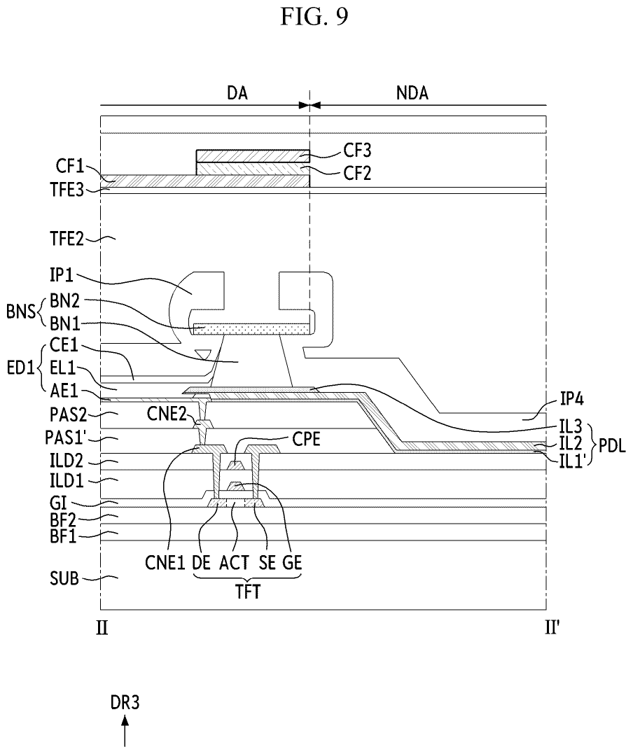

FIG. 9 is a cross-sectional view illustrating a portion of a display device according to one or more embodiments.

FIG. 9 is different from FIG. 8 in that a first passivation layer PAS1′ is removed from a partial area of the non-display area NDA, and the second interlayer insulating layer ILD2 may be exposed thereby. To enhance a sealing effect in the non-display area NDA, the first passivation layer PAS1′ may be removed. A first inorganic layer IL1′ of the pixel-defining layer PDL may cover a side of the first passivation layer PAS1′ and the second interlayer insulating layer ILD2.

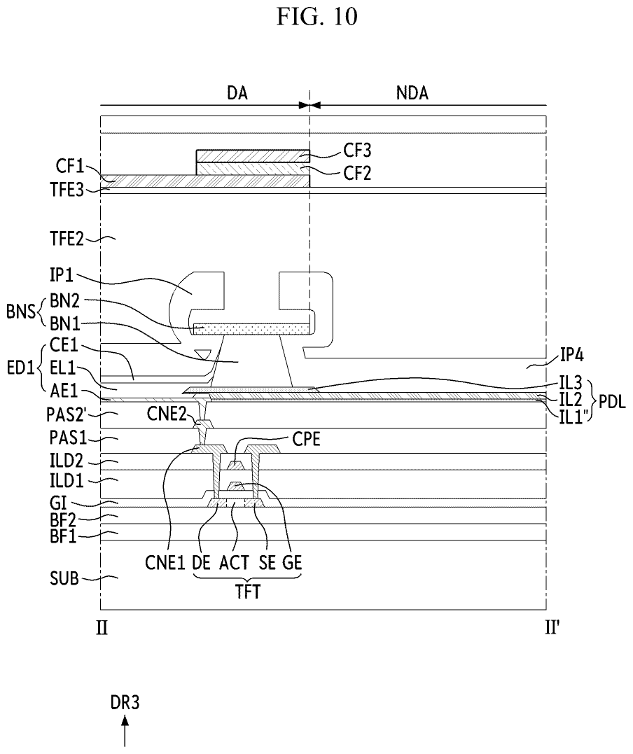

FIG. 10 is a cross-sectional view illustrating a portion of a display device according to one or more embodiments.

FIG. 10 is different from FIG. 8 in that a second passivation layer PAS2′ is extended in the non-display area NDA. The second passivation layer PAS2′ having a planarization function may be extended in the non-display area NDA. A first inorganic layer IL1″ of the pixel-defining layer PDL may cover an upper surface of the second passivation layer PAS2′.

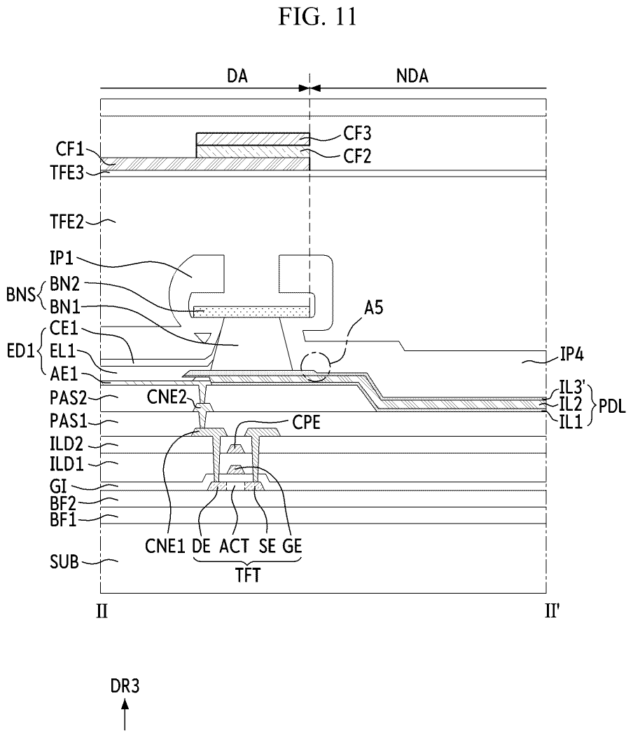

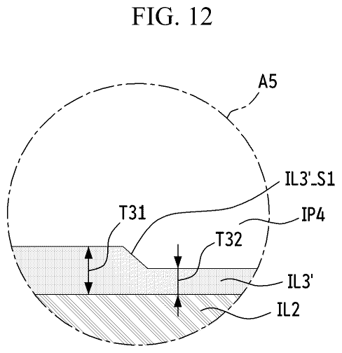

FIG. 11 is a cross-sectional view illustrating a portion of a display device according to one or more embodiments, and FIG. 12 is an enlarged cross-sectional view illustrating an area A5 of FIG. 11.

FIGS. 11 and 12 are different from FIG. 8 in that a thickness of a portion of a third inorganic layer IL3′ of the pixel-defining layer PDL is removed from the non-display area NDA. The third inorganic layer IL3′ is similar to the third inorganic layer IL3 of FIG. 9 in that the third inorganic layer IL3′ exposed by an etchant is removed during patterning for each color. However, only a partial thickness of the third inorganic layer IL3′ in the area exposed by the etchant is removed instead of a total thickness, and the third inorganic layer IL3′ may remain to be thin. Therefore, the thickness of the third inorganic layer IL3′ in the partial area of the non-display area NDA may be different from the thickness of the third inorganic layer IL3′ in the display area DA.

Referring to FIG. 12, a thickness of the third inorganic layer IL3′ may vary based on a boundary of a first side IL3′_S1. A thickness T31 of the third inorganic layer IL3′ adjacent to a bank structure BNS' may be greater than a thickness T32 of the third inorganic layer IL3′ far away from the bank structure BNS' based on the first side IL3′_S1.

Although the embodiments of the present disclosure have been described with reference to the accompanying drawings, it will be apparent to those skilled in the art that the present disclosure can be embodied in other forms without departing from the technical spirits and essential characteristics. Thus, the above embodiments are to be considered in all respects as illustrative and not restrictive.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the aspects of the present disclosure. Therefore, the disclosed embodiments are used in a generic and descriptive sense and not for purposes of limitation.

What is claimed is:

1. A display device comprising:
a substrate comprising a display area, and a non-display area around the display area;
a passivation layer above the substrate;
a light-emitting element above the passivation layer;
a pixel-defining layer above the passivation layer in the display area and the non-display area, and comprising:
a first inorganic layer above the substrate, a second inorganic layer above the first inorganic layer, and a third inorganic layer above the second inorganic layer, in the display area; and
the first inorganic layer and the second inorganic layer, in the non-display area;
a first bank above the pixel-defining layer; and
a second bank above the first bank, and extending further than a side of the first bank.

2. The display device of claim 1, wherein, in at least a portion of the non-display area, the second inorganic layer is uncovered by the third inorganic layer.

3. The display device of claim 1, wherein a side of the third inorganic layer that faces the non-display area extends further than, or is aligned with, a side of the second bank that faces the non-display area.

4. The display device of claim 1, wherein the pixel-defining layer is on an upper surface and a side of the passivation layer.

5. The display device of claim 4, wherein an angle between a lower surface and the side of the passivation layer is less than about 90°.

6. The display device of claim 5, wherein the pixel-defining layer comprises a first portion at a first height above the substrate, a second portion at a second height above the substrate, and a third portion at a third height above the substrate,
wherein the first height is greater than the second height and the third height,
wherein the second height is greater than the third height, and
wherein the first portion, the second portion, and the third portion of the pixel-defining layer are sequentially arranged in a longitudinal direction of the substrate.

7. The display device of claim 1, wherein the passivation layer extends in the display area and the non-display area.

8. The display device of claim 1, wherein a thickness of the first inorganic layer is less than a thickness of the second inorganic layer.

9. The display device of claim 1, wherein a thickness of the first inorganic layer is less than a thickness of a pixel electrode of the light-emitting element.

10. The display device of claim 9, wherein the second inorganic layer comprises a first side facing a side of the pixel electrode, and a second side extending further than the first side.

11. The display device of claim 1, wherein the second inorganic layer comprises a different material from the first inorganic layer and the third inorganic layer.

12. The display device of claim 11, wherein the first inorganic layer and the third inorganic layer comprise silicon nitride, and
wherein the second inorganic layer comprises one or more of silicon oxynitride or silicon oxide.

13. The display device of claim 1, wherein the passivation layer comprises one or more of an acrylic resin, an epoxy resin, a phenolic resin, a polyamide resin, or a polyimide resin.

14. The display device of claim 1, wherein, in the display area, the pixel-defining layer comprises a side extending further than the side of the first bank.

15. The display device of claim 1, further comprising a residual pattern at an edge of a pixel electrode of the light-emitting element, below the pixel-defining layer.

16. The display device of claim 1, wherein the light-emitting element comprises a pixel electrode above the passivation layer, a light-emitting layer above the pixel electrode, and a common electrode above the light-emitting layer and contacting the first bank.

17. The display device of claim 1, further comprising:
a first inorganic pattern above the light-emitting element in the display area; and
a second inorganic pattern above the pixel-defining layer in the non-display area, and spaced apart from the first inorganic pattern.

18. The display device of claim 17, wherein the first inorganic pattern is below a lower surface of the second bank.

19. A display device comprising:
a light-emitting element above a substrate;
a pixel-defining layer above the substrate, comprising a first inorganic layer above the substrate, a second inorganic layer above the first inorganic layer, and a third inorganic layer above the second inorganic layer;
a first bank above the pixel-defining layer; and
a second bank above the first bank, and extending further than a side of the first bank,
wherein the third inorganic layer has different respective thicknesses in an area overlapping the first bank and in an area non-overlapping with the first bank.

20. The display device of claim 19, wherein the thickness of the third inorganic layer in the area overlapping the first bank is greater than the thickness of the third inorganic layer in the area non-overlapping with the first bank.

21. An electronic device comprising:
A display device comprising a substrate comprising a display area, and a non-display area around the display area;
a passivation layer above the substrate;
a light-emitting element above the passivation layer;
a pixel-defining layer above the passivation layer in the display area and the non-display area, and comprising:
a first inorganic layer above the substrate, a second inorganic layer above the first inorganic layer, and a third inorganic layer above the second inorganic layer, in the display area; and
the first inorganic layer and the second inorganic layer, in the non-display area;
a first bank above the pixel-defining layer; and
a second bank above the first bank, and extending further than a side of the first bank.
